(19) United States
(12) Patent Application Publication
(10) Pub. No.: US 2013/0192671 A1
(43) Pub. Date: Aug. 1, 2013

(54) CONDUCTIVE METAL PASTE AND USE THEREOF

(71) Applicants: Kenneth Warren Hang, Cary, NC (US); Giovanna Laudisio, Bristol (GB); Yueli Wang, Cary, NC (US); Rosalynne Sophie Watt, Bristol (GB)

(72) Inventors: Kenneth Warren Hang, Cary, NC (US); Giovanna Laudisio, Bristol (GB); Yueli Wang, Cary, NC (US); Rosalynne Sophie Watt, Bristol (GB)

(73) Assignee: E I DU PONT DE NEMOURS AND COMPANY, Wilmington, DE (US)

(21) Appl. No.: 13/565,915

(22) Filed: Aug. 3, 2012

Related U.S. Application Data
(60) Provisional application No. 61/522,365, filed on Aug. 11, 2011.

(51) Int. Cl. H01L 31/0216; H01L 29/43; H01L 31/0224; H01L 31/18

(52) U.S. Cl. CPC H01L 31/02167; H01L 31/1884; H01L 29/43; H01L 31/022466
USPC 136/256; 252/514; 438/98; 257/749

(57) ABSTRACT

A conductive metal paste having no or only poor fire-through capability and including (a) particulate silver, (b) at least one lead-free glass frit including 0.5 to 15 wt. % SiO₂, 0.3 to 10 wt. % Al₂O₃ and 67 to 75 wt. % Bi₂O₃, wherein the weight percentages are based on the total weight of the glass frit, and (c) an organic vehicle, wherein the content of the particulate silver in the conductive metal paste is 60 to 92 wt.-%, based on total conductive metal paste composition, and wherein the conductive metal paste is free from zinc oxide and compounds capable of generating zinc oxide on firing.

### FIELD OF THE INVENTION

The invention is directed to a conductive metal paste and its use in the production of conductive metallizations on semiconductor substrates.

### TECHNICAL BACKGROUND OF THE INVENTION

U.S. Pat. No. 7,435,361 B2 discloses silver pastes comprising particulate silver, glass frit, organic vehicle and zinc oxide or compounds which generate zinc oxide on firing.

WO2010/117773 A1 and WO2010/117788 A1 disclose metal pastes having no or only poor fire-through capability. The metal pastes of WO2010/117773 A1 comprise (a) at least one electrically conductive metal powder selected from the group consisting of silver, copper and nickel, (b) at least one lead-containing glass frit with a softening point temperature (glass transition temperature, determined by differential thermal analysis DTA at a heating rate of 10 K/min) in the range of 571 to 636° C. and containing 53 to 57 wt. % (weight-%) of PbO, 25 to 29 wt. % of SiO₂, 2 to 6 wt. % of Al₂O₃ and 6 to 9 wt. % of B₂O₃ and (c) an organic vehicle, whereas the metal pastes of WO2010/117788 A1 comprise (a) at least one electrically conductive metal powder selected from the group consisting of silver, copper and nickel, (b) at least one lead-free glass frit with a softening point temperature (glass transition temperature, determined by differential thermal analysis DTA at a heating rate of 10 K/min) in the range of 550 to 611 ° C. and containing 11 to 33 wt. % of SiO₂, >0 to 7 wt. % of Al₂O₃ and 2 to 10 wt. % of B₂O₃ and (c) an organic vehicle.

### SUMMARY OF THE INVENTION

The invention relates to a conductive metal paste composition having no or only poor fire-through capability and including (a) particulate silver, (b) at least one lead-free glass frit including 0.5 to 15 wt. % SiO₂, 0.3 to 10 wt. % Al₂O₃ and 67 to 75 wt. % Bi₂O₃, wherein the weight percentages are based on the total weight of the glass frit, and (c) an organic vehicle, wherein the content of the particulate silver in the conductive metal paste is 60 to 92 wt. %, based on total conductive metal paste composition, and wherein the conductive metal paste composition is free from zinc oxide and compounds capable of generating zinc oxide on firing.

### DETAILED DESCRIPTION OF THE INVENTION

In the present description and the claims the term “fire-through capability” is used. It shall mean the ability of a metal paste to etch and penetrate through (fire through) a passivation or ARC (antireflective coating) layer on a silicon semiconductor surface during firing. In other words, a metal paste with fire-through capability is one that fires through a passivation or an ARC layer making electrical contact with the surface of the silicon semiconductor. Correspondingly, a metal paste with poor or even no fire through capability makes no electrical contact with the silicon semiconductor surface upon firing. To avoid misunderstandings; in this context the term “no electrical contact” shall not be understood absolute; rather, it shall mean that the contact resistivity between fired metal paste and silicon surface exceeds 1 Ω·cm², whereas, in case of electrical contact, the contact resistivity between fired metal paste and silicon surface is in the range of 1 to 10 mΩ·cm².

The contact resistivity can be measured by TLM (transfer length method). To this end, the following procedure of sample preparation and measurement may be used: A silicon wafer having an ARC or passivation layer (for example, a 75 nm thick SiNₓ layer) is screen printed on that layer with the metal paste to be tested in a pattern of parallel lines (for example, 127 μm wide and 6 μm thick lines with a spacing of 2.2 mm between the lines) and is then fired with the wafer reaching a peak temperature of, for example, 800° C. The fired wafer is laser-cutted into 10 mm by 28 mm long strips, where the parallel lines do not touch each other and at least 6 lines are included. The strips are then subject to conventional TLM measurement at 20° C. in the dark. The TLM measurement can be carried out using the device GP 4-Test Pro from GP Solar.

The conductive metal paste composition of the invention is a thick film conductive composition that can be applied, for example, by printing, in particular, by screen printing.

The conductive metal paste of the invention has no or only poor fire-through capability. Hence, it broadens the raw material basis with regard to such conductive metal pastes having no or only poor fire-through capability.

The conductive metal paste includes particulate silver. The particulate silver may be silver or a silver alloy with one or more other metals like, for example, copper. In case of silver alloys the silver content is, for example, 99.7 to below 100 wt. %. The particulate silver may be uncoated or at least partially coated with a surfactant. The surfactant may be selected from, but is not limited to, stearic acid, palmitic acid, lauric acid, oleic acid, capric acid, myristic acid and linolic acid and salts thereof, for example, ammonium, sodium or potassium salts.

The average particle size of the particulate silver is in the range of, for example, 0.5 to 5 μm. The particulate silver is present in the conductive metal paste in a proportion of 60 to 92 wt. %, or, in an embodiment, 65 to 84 wt. %, based on total conductive metal paste composition.

The term “average particle size” is used herein. It shall mean the average particle size (mean particle diameter, d50) determined by means of laser scattering. All statements made herein in relation to average particle sizes relate to average particle sizes of the relevant materials as are present in the conductive metal paste composition.

The particulate silver present in the conductive metal paste may or may not be accompanied by a small amount of one or more other particulate metals. Examples of other particulate metals include in particular copper powder. In an embodiment, the conductive metal paste is free from nickel and nickel alloys.

The conductive metal paste of the invention includes at least one lead-free glass frit as inorganic binder. The at least one lead-free glass frit includes 0.5 to 15 wt. % SiO₂, 0.3 to 10 wt. % Al₂O₃ and 67 to 75 wt. % Bi₂O₃. The weight percentages of SiO₂, Al₂O₃ and Bi₂O₃ may or may not total 100 wt. %. In case they do not total 100 wt. % the missing wt. % may in particular be contributed by one or more other constituents, for example, B₂O₃, ZnO, BaO, ZrO₂, P₂O₅, SnO₂ and/or BiF₃.

In an embodiment, the at least one lead-free glass frit includes 0.5 to 15 wt. % SiO₂, 0.3 to 10 wt. % Al₂O₃, 67 to 75 wt. % Bi₂O₃, and at least one of the following: >0 to 12 wt. % B₂O₃, >0 to 16 wt. % ZnO, >0 to 6 wt. % BaO. All weight percentages are based on the total weight of the glass frit.

Specific compositions for lead-free glass frits that can be used in the conductive metal paste of the invention are shown in Table 1. The table shows the wt. % of the various ingredients in glass frits A-N, based on the total weight of the glass frit.

TABLE 1

| | SiO₂ | Al₂O₃ | ZrO₂ | B₂O₃ | ZnO | BaO | Bi₂O₃ | P₂O₅ | SnO₂ | BiF₃ |
|---|---|---|---|---|---|---|---|---|---|---|
| A | 3.00 | 3.00 | | 12.00 | 7.00 | 5.00 | 70.00 | | | |
| B | 5.00 | 5.00 | | 8.00 | 7.00 | 5.00 | 70.00 | | | |
| C | 6.00 | 3.00 | | 6.00 | 7.00 | 4.00 | 74.00 | | | |
| D | 2.60 | 0.85 | | 8.10 | 13.20 | 2.25 | 73.00 | | | |
| E | 1.50 | 3.00 | | 7.50 | 14.50 | 3.50 | 70.00 | | | |
| F | 1.00 | 0.50 | | 9.50 | 13.00 | 3.00 | 73.00 | | | |
| G | 1.00 | 0.50 | | 9.50 | 13.00 | 3.00 | 73.00 | | | |
| H | 1.90 | 0.60 | | 8.20 | 13.50 | 2.60 | 73.20 | | | |
| I | 10.49 | 1.94 | 1.14 | | | | 73.94 | 2.70 | | 9.80 |
| J | 11.88 | 6.19 | | 9.72 | | | 72.21 | | | |
| K | 1.00 | 0.50 | | 9.50 | 13.00 | 3.00 | 73.00 | | | |
| L | 7.50 | 2.90 | | 7.50 | 11.00 | 1.90 | 69.20 | | | |
| M | 2.00 | 0.80 | | 8.40 | 13.40 | 2.40 | 72.50 | | 0.50 | |
| N | 7.17 | 7.17 | | 8.50 | 7.16 | | 70.00 | | | |

Generally, the conductive metal paste includes no glass frit other than the at least one lead-free glass frit.

The average particle size of the glass frit(s) is in the range of, for example, 0.5 to 4 μm. The total content of the at least one lead-free glass frit in the conductive metal paste is, for example, 0.25 to 8 wt. %, or, in an embodiment, 0.8 to 3.5 wt. %.

The preparation of the glass frits is well known and consists, for example, in melting together the constituents of the glass, in particular in the form of the oxides of the constituents, and pouring such molten composition into water to form the frit. As is well known in the art, heating may be conducted to a peak temperature in the range of, for example, 1050 to 1250° C. and for a time such that the melt becomes entirely liquid and homogeneous, typically, 0.5 to 1.5 hours.

The glass may be milled in a ball mill with water or inert low viscosity, low boiling point organic liquid to reduce the particle size of the frit and to obtain a frit of substantially uniform size. It may then be settled in water or said organic liquid to separate fines and the supernatant fluid containing the fines may be removed. Other methods of classification may be used as well.

The conductive metal paste includes an organic vehicle. A wide variety of inert viscous materials can be used as organic vehicle. The organic vehicle may be one in which the particulate constituents (particulate silver, glass frit, further optionally present inorganic particulate constituents) are dispersible with an adequate degree of stability. The properties, in particular, the rheological properties, of the organic vehicle may be such that they lend good application properties to the conductive metal paste composition, including: stable dispersion of insoluble solids, appropriate rheology for application, appropriate wettability of the paste solids, a good drying rate, and good firing properties. The organic vehicle used in the conductive metal paste may be a nonaqueous inert liquid. The organic vehicle may be an organic solvent or an organic solvent mixture; in an embodiment, the organic vehicle may be a solution of organic polymer(s) in organic solvent(s). In an embodiment, the polymer used for this purpose may be ethyl cellulose. Other examples of polymers which may be used alone or in combination include ethylhydroxyethyl cellulose, wood rosin, phenolic resins and poly(meth)acrylates of lower alcohols. Examples of suitable organic solvents include ester alcohols and terpenes such as alpha- or beta-terpineol or mixtures thereof with other solvents such as kerosene, dibutylphthalate, diethylene glycol butyl ether, diethylene glycol butyl ether acetate, hexylene glycol and high boiling alcohols.

In addition, volatile organic solvents for promoting rapid hardening after application of the conductive metal paste can be included in the organic vehicle. Various combinations of these and other solvents may be formulated to obtain the viscosity and volatility requirements desired.

The organic vehicle content in the conductive metal paste may be dependent on the method of applying the paste and the kind of organic vehicle used, and it can vary. In an embodiment, it may be from 10 to 39.75 wt. %, or, in an embodiment, it may be in the range of 12 to 35 wt. %, based on total conductive metal paste composition. The number of 10 to 39.75 wt. % includes organic solvent(s), possible organic polymer(s) and possible organic additive(s).

The organic solvent content in the conductive metal paste may be in the range of 5 to 25 wt. %, or, in an embodiment, 10 to 20 wt. %, based on total conductive metal paste composition.

The organic polymer(s) may be present in the organic vehicle in a proportion in the range of 0 to 20 wt. %, or, in an embodiment, 5 to 10 wt. %, based on total conductive metal paste composition.

The conductive metal paste may include one or more organic additives, for example, surfactants, thickeners, rheology modifiers and stabilizers. The organic additive(s) may be part of the organic vehicle. However, it is also possible to add the organic additive(s) separately when preparing the conductive metal paste. The organic additive(s) may be present in the conductive metal paste in a total proportion of, for example, 0 to 10 wt. %, based on total conductive metal paste composition.

The conductive metal paste is free from zinc oxide and compounds capable of generating zinc oxide on firing. In an embodiment it is also free from other oxides like metal oxides other than zinc oxide, and from compounds capable of generating such oxides on firing.

The conductive metal paste is a viscous composition, which may be prepared by mechanically mixing the particulate silver and the at least one lead-free glass frit with the organic vehicle. In an embodiment, the manufacturing method power mixing, a dispersion technique that is equivalent to the traditional roll milling, may be used; roll milling or other mixing technique can also be used.

The conductive metal paste can be used as such or may be diluted, for example, by the addition of additional organic solvent(s); accordingly, the weight percentage of all the other constituents of the metal paste may be decreased.

The application viscosity of the conductive metal paste may be, for example, 20 to 400 Pa·s when measured at a spindle speed of 10 rpm and 25° C. by a utility cup using a Brookfield HBT viscometer and #14 spindle.

The conductive metal paste of the invention can be used in the manufacture of conductive metallizations on semiconductor substrates.

Therefore the invention relates also to a method for the manufacture of conductive metallizations on the surface of semiconductor substrates. The method includes the steps:
(1) applying a conductive metal paste in any one of its embodiments described herein on the surface of a semiconductor substrate, and
(2) firing the applied conductive metal paste to form a conductive metallization.

Said manufacturing method includes the production of one or more conductive metallizations per semiconductor substrate. Examples of such conductive metallizations include electrodes, parts of electrodes or other metal contacts on semiconductor substrates.

The semiconductor substrates include silicon semiconductors in particular.

Examples of semiconductor substrates include solar cells, in particular, silicon solar cells. The silicon solar cells may be mono- or polycrystalline silicon solar cells, for example.

The metallizations may be applied in a fired thickness within a range of, for example, 10 to 60 μm, and to various places on the surface of the semiconductor or semiconductors, in each case dependent on the type of semiconductor or solar cell as well as dependent on the desired function of the conductive metallization in question. The semiconductor surface area to be covered by the conductive metallization may be p- or n-type silicon and the silicon surface may be provided with or without a dielectric layer thereon. Examples include p- or n-type emitter surfaces of solar cells, which may or may not be covered with a dielectric layer. Examples of dielectric layers include conventional dielectric layers such as layers of TiOₓ, SiOₓ, TiOₓ/SiOₓ, SiNₓ or a dielectric stack of SiNₓ/SiOₓ. The thickness of such dielectric layers lies in the range of, for example, 0.05 and 0.1 μm and they may be deposited by plasma CVD (chemical vapor deposition), for example. Such a dielectric layer may serve as an ARC and/or passivation layer, for example. Other examples of silicon semiconductor surface areas to be covered by the metallization include the inside of the holes of MWT (metal wrap through) silicon solar cells. Also dependent on the desired function of a respective conductive metallization, it can be applied from the conductive metal paste of the invention in a variety of patterns or shapes including, for example, fine lines, busbars and/or tabs, the fine lines being arranged for example, as parallel lines or as a grid or web.

The manufacture of the metallizations may be performed by applying the conductive metal paste to the semiconductor surface. Application methods include, for example, pen writing and printing, in particular, screen printing. After application of the conductive metal paste it is typically dried and then fired to form the finished conductive metallization. Firing may be performed, for example, for a period of 1 to 5 minutes with the semiconductor substrate reaching a peak temperature in the range of, for example, 800 to 975° C. Firing can be carried out making use of, for example, single or multi-zone belt furnaces, in particular, multi-zone IR belt furnaces. Firing may happen in the presence of oxygen, in particular, in the presence of air. During firing the organic substance including non-volatile organic material and the organic portion not evaporated during the possible drying step may be removed, i.e. burned and/or carbonized, in particular, burned. The organic substance removed during firing includes organic solvent(s), possible organic polymer(s) and possible organic additive(s). There is a further process taking place during firing, namely sintering of the at least one lead-free glass frit. As already mentioned above, the conductive metal paste of the invention has no or only poor fire-through capability and does therefore not or essentially not fire through a dielectric layer optionally present on the semiconductor surface; the conductive metal paste of the present invention does also not damage the semiconductor surface as such.

### EXAMPLES

The following examples illustrate the determination of the fire-through capability of silver pastes. The examples cited here relate to metal pastes fired onto the front side of conventional solar cells having a p-type silicon base and n-type emitter.

(1) Manufacture of Test Samples

(i) Example Silver Pastes 1 to 3:

The compositions of the silver pastes 1 to 3 are displayed in Table 2. The pastes comprised of silver powder (average particle size 2 μm), organic vehicle (polymeric resins and organic solvents) and glass frit (average particle size 8 μm). Table 3 provides composition data of the glass frit type employed.

TABLE 2

Composition (wt. %)

| Silver | | organic | |
|---|---|---|---|
| Paste | silver powder | vehicle | glass frit type |
| 1 | 88.83 | 10.67 | 0.5 of type 1 |
| 2 | 88.83 | 10.67 | 0.5 of type 2 |
| 3 | 88.5 | 11.25 | 0.25 of type 1 |

TABLE 3

| Glass | Glass Components (wt. %) | | | | | | | | |
|---|---|---|---|---|---|---|---|---|---|
| Type | SiO₂ | Al₂O₃ | B₂O₃ | PbO | TeO₂ | Li₂O | ZnO | BaO | Bi₂O₃ |
| 1 | 1 | 0.5 | 9.5 | — | — | — | 13 | 3 | 73 |
| 2 | | | 0.48 | 44.51 | 47.74 | 0.44 | | | 6.83 |

(ii) Formation of TLM Samples:

On the front face of Si substrates (200 μm thick multicrystalline silicon wafers of area 243 cm², p-type (boron) bulk silicon, with an n-type diffused POCl₃ emitter, surface texturized with acid, 75 nm thick SiNₓ ARC layer on the wafer's emitter applied by CVD) having a 30 μm thick aluminum electrode (screen-printed from PV381 Al composition commercially available from E. I. Du Pont de Nemours and Company) the silver pastes 1-3 were screen-printed as approximately 100 μm wide and approximately 5 μm thick parallel finger lines having a distance of 2.2 mm between each other. The aluminum paste and the silver paste were dried before cofiring.

The printed wafers were then fired in a Despatch furnace at a belt speed of 3000 mm/min with zone temperatures defined as zone 1=500° C., zone 2=525° C., zone 3=550° C., zone 4=600° C., zone 5=930° C. and the final zone set at 890° C., thus the wafers reaching a peak temperature of 800° C.

To produce TLM samples, the fired wafers were subsequently laser scribed and fractured into 10 mm×28 mm TLM samples, where the parallel silver metallization lines did not touch each other. Laser scribing was performed using a 1064 nm infrared laser supplied by Optek.

(2) Test Procedures and Results

The TLM samples were measured by placing them into a GP 4-Test Pro instrument available from GP Solar for the purpose of measuring contact resistivity. The measurements were performed at 20° C. with the samples in darkness. The test probes of the apparatus made contact with 6 adjacent fine line silver electrodes of the TLM samples, and the contact resistivity (pc) was recorded. Paste 1 showed poor fire through capability in comparison to paste 2 which showed good fire through capability. In the case of paste 3 contact resistivity was recorded as >364 Ω·cm²; in other words, the contact resistivity exceeded the upper measurable limit for the GP 4-Test Pro equipment.

Table 4 presents the measured contact resistivity data.

TABLE 4

| | | Contact |
|---|---|---|
| Example | Silver paste | Resistivity |
| 1 (according to | 1 | >131 mΩ · cm² |
| the invention) | | |
| 2 (comparative) | 2 | >4.69 mΩ · cm² |
| 3 (according to | 3 | >364 Ω · cm² |
| the invention) | | |

What is claimed is:

1. A conductive metal paste having no or only poor fire-through capability and comprising (a) particulate silver, (b) at least one lead-free glass frit comprising 0.5 to 15 wt. % SiO₂, 0.3 to 10 wt. % Al₂O₃ and 67 to 75 wt. % Bi₂O₃, wherein the weight percentages are based on the total weight of the glass frit, and (c) an organic vehicle, wherein the content of the particulate silver in the conductive metal paste is 60 to 92 wt.-%, based on total conductive metal paste composition, and wherein the conductive metal paste composition is free from zinc oxide and compounds capable of generating zinc oxide on firing.

2. The conductive metal paste of claim 1, wherein the at least one lead-free glass frit contains also at least one of the following: >0 to 12 wt. % B₂O₃, >0 to 16 wt. % ZnO, >0 to 6 wt. % BaO.

3. The conductive metal paste of claim 1 comprising no glass frit other than the at least one lead-free glass frit.

4. The conductive metal paste of claim 1, wherein the total content of the at least one lead-free glass frit in the conductive metal paste is 0.25 to 8 wt. %.

5. The conductive metal paste of claim 1, wherein the organic vehicle content is 10 to 39.75 wt. %.

6. A method for the manufacture of a conductive metallization on the surface of a semiconductor substrate comprising the steps:
(1) applying the conductive metal paste of claim 1 on the surface of a semiconductor substrate, and
(2) firing the applied conductive metal paste to form a conductive metallization.

7. The method of claim 6, wherein the conductive metallization is selected from the group consisting of electrodes, parts of electrodes and other metal contacts.

8. The method of claim 6, wherein the semiconductor substrate is a solar cell.

9. Use of the conductive metal paste of claim 1 in the manufacture of conductive metallizations on semiconductor substrates.

10. The use of claim 9, wherein the conductive metallizations are selected from the group consisting of electrodes, parts of electrodes and other metal contacts.

11. The use of claim 9, wherein the semiconductor substrates are solar cells.

12. A semiconductor substrate provided with one or more conductive metallizations made by the method of claim 6.

13. A solar cell provided with one or more conductive metallizations made by the method of claim 8.
